(19) United States
(12) Patent Application Publication
(10) Pub. No.: US 2021/0280451 A1
(43) Pub. Date: Sep. 9, 2021

(54) LOW TEMPERATURE STEAM FREE OXIDE GAPFILL

(71) Applicant: Applied Materials, Inc., Santa Clara, CA (US)

(72) Inventors: Jung Chan Lee, Sunnyvale, CA (US); Praket P. Jha, San Jose, CA (US); Jingmei Liang, San Jose, CA (US); Shuchi Sunil Ojha, Redwood City, CA (US)

(73) Assignee: Applied Materials, Inc., Santa Clara, CA (US)

(21) Appl. No.: 16/808,688

(22) Filed: Mar. 4, 2020

(51) Int. Cl. H01L 21/762; H01L 21/3105; H01L 21/02

(52) U.S. Cl. CPC H01L 21/76224; H01L 21/02164; H01L 21/02348; H01L 21/31053

(57) ABSTRACT

Provided are methods of depositing a film in high aspect ratio (AR) structures with small dimensions. The method provides flowable deposition for seamless gap-fill, UV cure for increasing film density, film conversion to silicon oxide at low temperature, and film densification by low temperature inductively coupled plasma (ICP) treatment (<400° C.).

### TECHNICAL FIELD

Embodiments of the disclosure generally relate to methods for filling substrate features. More particularly, embodiments of the disclosure are directed to methods for filling a substrate feature with a seamless conformal and/or selective (dry/wet) etch method.

### BACKGROUND

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor, and are now being applied in many integrated circuits. However, finFETs have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a horizontal gate all around (hGAA) structure. The hGAA device structure includes several lattice matched channels suspended in a stacked configuration and connected by source/drain regions. It is believed that the hGAA structure provides good electrostatic control and can find broad adoption in complementary metal oxide semiconductor (CMOS) wafer manufacturing.

In microelectronics device fabrication there is a need to fill narrow trenches having aspect ratios (AR) greater than 10:1 with no voiding for many applications. One application is for shallow trench isolation (STI). For this application, the film needs to be of high quality throughout the trench (having, for example, a wet etch rate ratio less than two) with very low leakage. One method that has had past success is flowable CVD. In this method, oligomers are carefully formed in the gas phase which condense on the surface and then “flow” into the trenches. The as-deposited film is of very poor quality and requires processing steps such as steam anneals and UV-cures.

As the dimensions of the structures decrease and the aspect ratios increase post curing methods of the as deposited flowable films become difficult. Resulting in films with varying composition throughout the filled trench.

Flowable films, e.g. flowable CVD films provide a particular solution to resolve the issue of void or seam containing gap fill at contact levels, but flowable films suffer from poor film quality, or require additional treatment steps to improve film quality. Therefore, there is a need for an improved method to create a seamless gap fill.

### SUMMARY

One or more embodiments of the disclosure are directed to a processing method. The method comprises forming a film on a substrate surface by exposing the substrate surface to a precursor mixture, the precursor mixture comprising one or more of a silane, trisilylamine (TSA), and a reactant gas; exposing the film to a remote plasma source to deposit a flowable polysilazane film; curing the flowable polysilazane film; converting the flowable polysilazane film to a silicon oxide film; and densifying the silicon oxide film.

Another embodiment of the disclosure is directed to a processing method. The processing method comprises: forming a plurality of film stacks on a substrate, the film stack comprising alternating layers of silicon germanium (SiGe) and silicon (Si); etching the film stack to form an opening extending a depth from a top surface of the film stack to a bottom surface, the opening having a width defined by a first sidewall and a second sidewall; depositing a film on the top surface of the film stack, and on the first sidewall, the second sidewall, and the bottom surface of the opening; exposing the film to a remote plasma source to deposit a flowable polysilazane film; curing the flowable polysilazane film; converting the flowable polysilazane film to a silicon oxide film; and densifying the silicon oxide film.

Other embodiments of the disclosure are directed to a non-transitory computer readable medium including instructions, that, when executed by a controller of a processing chamber, causes the processing chamber to perform operations of: expose a substrate surface to a precursor mixture to form a film on the substrate surface; expose the film to a remote plasma source to deposit a flowable polysilazane film; cure the flowable polysilazane film; convert the flowable polysilazane film to a silicon oxide film; and densify the silicon oxide film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional view of a substrate feature in accordance with one or more embodiment of the disclosure;

FIG. 2 shows a cross-sectional view of a substrate feature in accordance with one or more embodiment of the disclosure; and

FIG. 3 shows a process flow in accordance with one or more embodiment of the disclosure; and

FIG. 4 illustrates a cluster tool according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor”, “reactant”, “reactive gas” and the like are used interchangeably to refer to any gaseous species that can react with the substrate surface.

As used herein, the term “gate all-around (GAA),” is used to refer to an electronic device, e.g. a transistor, in which the gate material surrounds the channel region on all sides. The channel region of a GAA transistor may include nano-wires or nano-slabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

Previous methods introduced high temperature steam anneal to convert films to silicon oxide and to densify the films for use in transistor. Steam anneal can damage silicon germanium (SiGe) and silicon (Si) fins in a transistor (e.g. GAA transistor), causing SiGe oxidation and dopant diffusion. The method of one of more embodiments, thus, advantageously eliminates steam anneal. Accordingly, the method of one or more embodiments advantageously provides flowable deposition for good gap-fill, UV cure for increasing film density, film conversion to silicon oxide at low temperature using water (H₂O) treatment (<100° C.), and film densification by low temperature inductively coupled plasma (ICP) treatment (<400° C.).

Embodiments of the disclosure provide methods of depositing a film in high aspect ratio (AR) structures with small dimensions. Some embodiments advantageously provide methods involving cyclic deposition-etch-treatment processes that can be performed in a cluster tool environment. Some embodiments advantageously provide seam-free high quality films to fill up high aspect ratio (AR) trenches with small dimensions.

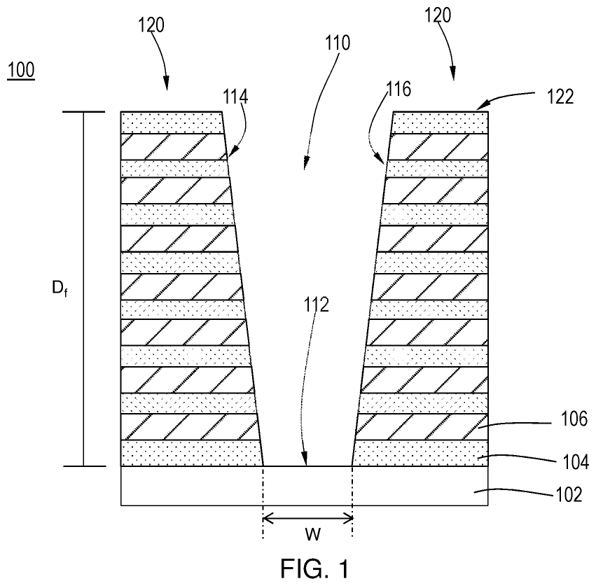

One or more embodiments of the disclosure are described with reference to the Figures. FIG. 1 shows a partial cross-sectional view of an electronic device 100 with a feature 110. The Figures show electronic devices having a single feature for illustrative purposes; however, those skilled in the art will understand that there can be more than one feature. The shape of the feature 110 can be any suitable shape including, but not limited to, trenches and vias. In one or more embodiments, the electronic device 100 includes a plurality of fins 120 on the substrate surface 102.

As used in this regard, the term “feature” means any intentional surface irregularity. Suitable examples of features include, but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, about 10:1, about 15:1, about 20:1, about 25:1, about 30:1, about 35:1 or about 40:1.

In one or more embodiments, the fins 120 comprise alternating layers of a first material 104 and a second material 106. The first material 104 and second material 106 of some embodiments are different materials. In some embodiments, the first material 104 comprises silicon (Si). In some embodiments, the second material 106 comprises silicon germanium (SiGe). The first material 104 and second material 106 can be any suitable thickness and can be deposited by any suitable technique known to the skilled artisan.

In one or more embodiments, the at least one feature 110 extends from a top surface 122 of the plurality of fins 120 to a feature depth D_{f} to a bottom surface 112. The at least one feature 110 has a first sidewall 114 and a second sidewall 116 that define a width W of the at least one feature 110. In one or more embodiments, the open area formed by the sidewalls 114, 116 and bottom 112 are also referred to as a gap. In one or more embodiments, the width W is homogenous along the depth D_{f} of the at least one feature 110. In other embodiments, the width, W, is greater at the top of the at least one feature 110 than the width, W, at the bottom surface 112 of the at least one feature 110.

In one or more embodiments, the semiconductor substrate 102 can be any suitable substrate material. In one or more embodiments, the semiconductor substrate 102 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), copper indium gallium selenide (CIGS), other semiconductor materials, or any combination thereof. In one or more embodiments, the semiconductor substrate 102 comprises one or more of silicon (Si), germanium (Ge), gallium (Ga), arsenic (As), indium (In), phosphorus (P), copper (Cu), or selenium (Se). Although a few examples of materials from which the substrate 102 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In one or more embodiments, the at least one feature 110 comprises a memory hole or a word line slit. Accordingly, in one or more embodiments, the electronic device 100 comprises a gate all-around (GAA) transistor.

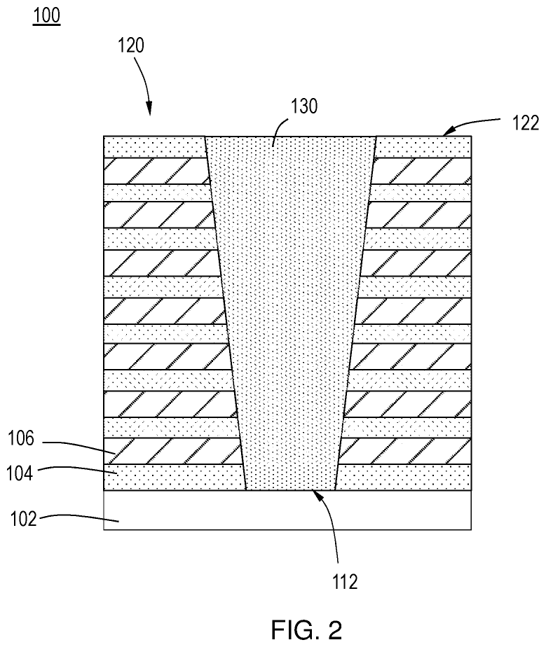

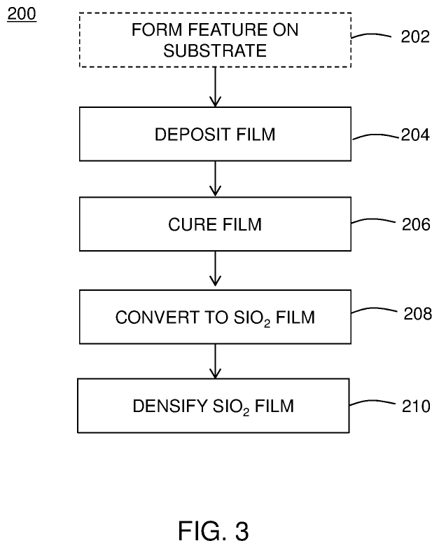

FIG. 2 shows a partial cross-sectional view of an electronic device in accordance with one or more embodiments of the disclosure. FIG. 3 shows a processing method 200 in accordance with one or more embodiments of the disclosure. With reference to FIG. 2 and FIG. 3, in one or more embodiments, at least one feature 110 is formed on an electronic device 100. In some embodiments, the electronic device 100 is provided for processing prior to operation 202. As used in this regard, the term “provided” means that the substrate is placed into a position or environment for further processing. In one or more embodiments, the electronic device 100 has at least one feature 110 already formed thereon. In other embodiments, at operation 202, at least one feature 110 is formed on electronic device 100. In one or more embodiments, the at least one feature extends a feature depth, D_{f}, from the substrate surface to a bottom surface, the at least one feature having a width, W, defined by a first sidewall 114 and a second sidewall 116.

In one or more embodiments, at operation 204, a film 130 is formed on the substrate surface 102 and the walls 114, 116 and the bottom 112 of the at least one feature 110. In one or more embodiments, the film 130 may have a void or a gap or a seam (not illustrated) located within the width, W, of the at least one feature 110.

In one or more embodiments, the film 130 can be comprised of any suitable material. In some embodiments, the film 130 comprises a polysilazane (SiₓN_{y}H_{z}). In one or more embodiments, the film 130 is formed by flowable chemical vapor deposition (FCVD) or plasma-enhanced chemical vapor deposition (PECVD).

The PECVD process of some embodiments comprises exposing the substrate surface to a reactive gas or a reactant gas. The reactive gas can include a mixture of one or more species. In one or more embodiments, the reactant gas comprises one or more of argon (Ar), oxygen (O₂), hydrogen (H₂), nitrogen (N₂), hydrogen/nitrogen (H₂/N₂), and ammonia (NH₃).

In one or more embodiments, the precursor mixture comprises one or more of a silane, trisilylamine (TSA), and a reactant gas. In one or more embodiments, the silane comprises one or more of silane, disilane, trisilane, tetrasilane, higher order silanes, and substituted silanes. In specific embodiments, the silane comprises one or more of silane and trisilylamine (TSA).

In one or more embodiments, the precursor mixture comprises a silane and a reactant gas. In one or more embodiments, the precursor mixture comprises a silane, trisilylamine (TSA), and a reactant gas. In one or more embodiments, the precursor mixture comprises silane, trisilylamine (TSA), and a reactant gas.

The plasma gas can be any suitable gas that can be ignited to form a plasma and/or can act as a carrier or diluent for the precursor. In one or more embodiments, the plasma gas comprises ammonia (NH₃), and the ammonia is used a plasma treatment to activate one or more of the precursors.

In one or more embodiments, a high plasma density dissociates the reactant gases (e.g. argon (Ar), oxygen (O₂), hydrogen (H₂), nitrogen (N₂), hydrogen/nitrogen (H₂/N₂), and ammonia (NH₃)) to generate radicals, which then react with other precursors downstream in the chamber to result in a flowable polysilazane (SiₓN_{y}H_{z}) based film 130 on the substrate 102. In one or more embodiments, this flowable deposition suppresses any gap-fill void or seam in the feature 110. In one or more embodiments, exposing the film 130 to the remote plasma source (RPS) dissociates the reactant gas and generates a radical that reacts with one or more of the silane and the trisilylamine (TSA).

In one or more embodiments, the plasma comprises one or more of nitrogen (N₂), argon (Ar), helium (He), hydrogen (H₂), carbon monoxide (CO), oxygen (O₂), ammonia (NH₃), or carbon dioxide (CO₂). In some embodiments, the plasma is a remote plasma.

In one or more embodiments, the plasma may be generated remotely or within the processing chamber.

In one or more embodiments, the deposition process is carried out in a process volume at pressures ranging from 0.1 mTorr to 10 Torr, including a pressure of about 0.1 mTorr, about 1 mTorr, about 10 mTorr, about 100 mTorr, about 500 mTorr, about 1 Torr, about 2 Torr, about 3 Torr, about 4 Torr, about 5 Torr, about 6 Torr, about 7 Torr, about 8 Torr, about 9 Torr, and about 10 Torr.

The precursor-containing gas mixture may further include one or more of a dilution gas selected from helium (He), argon (Ar), xenon (Xe), nitrogen (N₂), or hydrogen (H₂). The dilution gas of some embodiments comprises a compound that is inert gas relative to the reactants and substrate materials.

The plasma (e.g., capacitive-coupled plasma) may be formed from either top and bottom electrodes or side electrodes. The electrodes may be formed from a single powered electrode, dual powered electrodes, or more electrodes with multiple frequencies such as, but not limited to, 350 KHz, 2 MHz, 13.56 MHz, 27 MHz, 40 MHz, 60 MHz and 100 MHz, being used alternatively or simultaneously in a CVD system with any or all of the reactant gases listed herein to deposit a thin film of dielectric. In some embodiments, the plasma is a capacitively coupled plasma (CCP). In some embodiments, the plasma is an inductively coupled plasma (ICP). In some embodiments, the plasma is a microwave plasma.

In one or more embodiments, the plasma is an inductively coupled plasma (ICP) or a conductively coupled plasma (CCP). Any suitable power can be used depending on, for example, the reactants, or the other process conditions. In some embodiments, the plasma is generated with a plasma power in the range of about 10 W to about 10 kW.

In one or more embodiments, the flowable film 130 can be formed at any suitable temperature. In some embodiments, the flowable film 130 is formed at a temperature in the range of about −10° C. to about 400° C.

Suitable silicon precursors include, but are not limited to, silane, disilane, dichlorosilane (DCS), trisilane, tetrasilane, etc. In some embodiments, silane, disilane, trisilane, tetrasilane, higher order silanes, substituted silanes, or trisilylamine (TSA) reactants are used with another precursor (e.g. co-flow with another Si-containing precursor) in a flowable process to deposit films of various compositions.

In some embodiments, the flowable CVD film is doped with another element. For example, in one or more embodiments, the flowable CVD film is doped with one or more of boron (B), arsenic (As), or phosphorous (P). In one or more embodiments, the flowable CVD films are doped with elements such as boron (B) and phosphorous (P) to improve film properties. In one or more embodiments, precursors containing boron and phosphorous are either co-flowed with the precursor of general formula I and trisilylamine (TSA) during the deposition process or are infiltrated after the deposition is done.

In some embodiments, the film 130 forms conformally on the at least one feature 110. As used herein, the term “conformal”, or “conformally”, refers to a layer that adheres to and uniformly covers exposed surfaces with a thickness having a variation of less than 1% relative to the average thickness of the film. For example, a 1,000 Å thick film would have less than 10 Å variations in thickness. This thickness and variation includes edges, corners, sides, and the bottom of recesses. For example, a conformal layer deposited by CVD in various embodiments of the disclosure would provide coverage over the deposited region of essentially uniform thickness on complex surfaces.

In some embodiments, the film 130 is a continuous film. As used herein, the term “continuous” refers to a layer that covers an entire exposed surface without gaps or bare spots that reveal material underlying the deposited layer. A continuous layer may have gaps or bare spots with a surface area less than about 1% of the total surface area of the film.

In one or more embodiments, the flowable CVD film deposits on the wafer (temperature of the wafer can be from −10° C. to 600° C.) and due to their flowability, polymers flow through trenches and make a gap-fill.

At operation 204, film 130 is cured by ultraviolet (UV) energy. In one or more embodiments, film 130 is cured by exposing the flowable polysilazane film 130 to ultraviolet (UV) light. In one or more embodiments, such UV curing shrinks the film 130 under the low stress at low temperature and increases the film density and silicon content by breaking Si—H bonding, followed by forming Si—Si bonding and then by reducing the H content of the film. In one or more embodiments, this UV step increases film density in feature 110, which improves film quality. In one or more embodiments, reactive UV with ozone (O₃) or oxygen (O₂) ambient improves film conversion into SiO in the following wet treatment step.

Without intending to be bound by theory, it is thought that a steam anneal step can be eliminated in curing the film, thus preventing damage or oxidation to the SiGe, Si fin. During a high temperature steam anneal process, oxygen (O₂), hydrogen/oxygen (H₂/O₂), and water (H₂O) can diffuse into Si, SiGe fin, undesirably damaging or oxidizing the SiGe, Si fin. Accordingly, in one or more embodiments, the process is conducted in the absence of a steam anneal. In other embodiments, the process is conducted in the absence of a high temperature steam anneal process.

At operation 206, film 130, which comprises polysilazane, is converted to a silicon oxide (SiOₓ) film by breaking Si—Si, Si—N, Si—H followed by oxygen incorporation to form Si—O—Si network during low temperature H₂O treatment (<100° C.). This step enables full conversion into SiO₂ as eliminating any impurity including nitrogen (N₂), fluorine (F).

At operation 208, the silicon oxide film is densified by low temperature inductive coupled plasma (ICP) treatment (<400 t) as removing OH in film using ion bombardment energy. In one or more embodiments, the ICP treatment improves not only film quality, such as low wet etch rate, but also improves electrical properties such as leakage current/breakdown voltage. Reactive ambient such as oxygen (02), hydrogen/oxygen (H₂/O₂) improves film quality and eliminated impurities further.

According to one or more embodiments, the substrate is subjected to processing prior to and/or after forming the layer. This processing can be performed in the same chamber or in one or more separate processing chambers. In one or more embodiments, the substrate is then moved to another processing chamber for further processing. The substrate can be moved directly from the physical vapor deposition chambers to the separate processing chamber, or it can be moved from the physical vapor deposition chambers to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

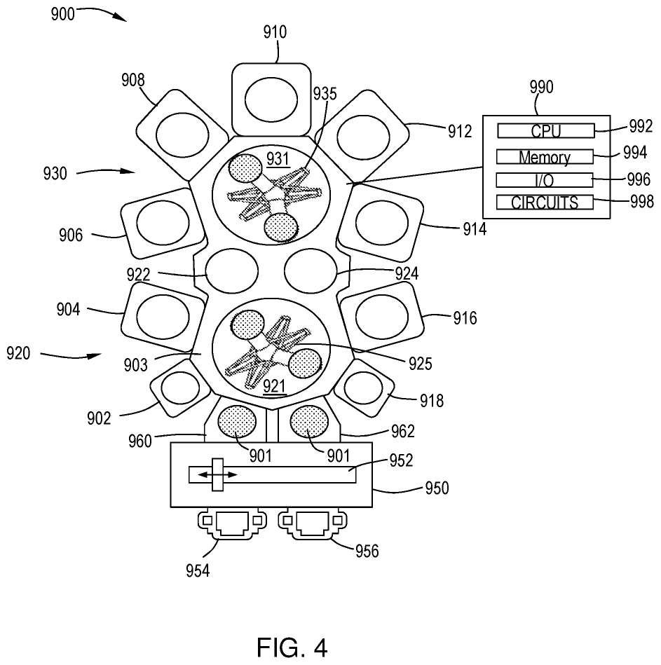

Additional embodiments of the disclosure are directed to processing tools 900 for the formation of the devices and practice of the methods described, as shown in FIG. 4. The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a physical vapor deposition chamber, a UV curing chamber, an ICP chamber, an etching chamber, and the like. The particular arrangement of process chambers and components can be varied depending on the cluster tool and should not be taken as limiting the scope of the disclosure.

In the embodiment shown in FIG. 4, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930, or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit (CPU) 992, memory 994, inputs/outputs (I/O) 996, and support circuits 998. The controller 990 may control the processing tool 900 directly, or via computers (or controllers) associated with particular process chamber and/or support system components.

In one or more embodiments, the controller 990 may be one of any form of general-purpose computer processor that can be used in an industrial setting for controlling various chambers and sub-processors. The memory 994 or computer readable medium of the controller 990 may be one or more of readily available memory such as non-transitory memory (e.g. random access memory (RAM)), read only memory (ROM), floppy disk, hard disk, optical storage media (e.g., compact disc or digital video disc), flash drive, or any other form of digital storage, local or remote. The memory 994 can retain an instruction set that is operable by the processor (CPU 992) to control parameters and components of the processing tool 900.

The support circuits 998 are coupled to the CPU 992 for supporting the processor in a conventional manner. These circuits include cache, power supplies, clock circuits, input/output circuitry and subsystems, and the like. One or more processes may be stored in the memory 994 as software routine that, when executed or invoked by the processor, causes the processor to control the operation of the processing tool 900 or individual processing units in the manner described herein. The software routine may also be stored and/or executed by a second CPU (not shown) that is remotely located from the hardware being controlled by the CPU 992.

Some or all of the processes and methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 990 has one or more configurations to execute individual processes or sub-processes to perform the method. The controller 990 can be connected to and configured to operate intermediate components to perform the functions of the methods. For example, the controller 990 can be connected to and configured to control a physical vapor deposition chamber.

Processes may generally be stored in the memory 994 of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the system controller 990 has a configuration to control a chemical vapor deposition chamber to deposit a film on a wafer at a temperature in the range of about 20° C. to about 400° C. and control a remote plasma source to form a polysilazane film on the wafer.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising a physical vapor deposition chamber and a remote plasma source; a UV curing chamber; an ICP chamber; and a controller connected to the central transfer station and the plurality of process stations, the controller configured to activate the robot to move the wafer between process stations, and to control a process occurring in each of the process stations.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A processing method comprising:
forming a film on a substrate surface by exposing the substrate surface to a precursor mixture, the precursor mixture comprising one or more of a silane, trisilylamine (TSA), and a reactant gas;
exposing the film to a remote plasma source to deposit a flowable polysilazane film;
curing the flowable polysilazane film;
converting the flowable polysilazane film to a silicon oxide film; and
densifying the silicon oxide film.

2. The method of claim 1, wherein the silane comprises one or more of silane, disilane, trisilane, tetrasilane, higher order silanes, and substituted silanes.

3. The method of claim 2, wherein exposing the film to the remote plasma source (RPS) dissociates the reactant gas and generates a radical that reacts with one or more of the silane and trisilylamine (TSA).

4. The method of claim 2, wherein the precursor mixture comprises silane, trisilylamine (TSA), and the reactant gas.

5. The method of claim 1, wherein the reactant gas comprises one or more of argon (Ar), oxygen (O₂), hydrogen (H₂), nitrogen (N₂), hydrogen/nitrogen (H₂/N₂), and ammonia (NH₃).

6. The method of claim 1, wherein curing comprises exposing the flowable polysilazane film to ultraviolet (UV) light.

7. The method of claim 1, wherein densifying the silicon oxide film comprises treating the silicon oxide film with inductively coupled plasma (ICP) at a temperature less than about 400° C.

8. The method of claim 1, where the substrate surface has a plurality of fins and at least one feature thereon.

9. The method of claim 8, wherein the plurality of fins comprise alternating layers of silicon germanium (SiGe) and silicon (Si).

10. A processing method comprising:
forming a plurality of film stacks on a substrate, the film stack comprising alternating layers of silicon germanium (SiGe) and silicon (Si);
etching the film stack to form an opening extending a depth from a top surface of the film stack to a bottom surface, the opening having a width defined by a first sidewall and a second sidewall;
depositing a film on the top surface of the film stack, and on the first sidewall, the second sidewall, and the bottom surface of the opening;
exposing the film to a remote plasma source to deposit a flowable polysilazane film;
curing the flowable polysilazane film;
converting the flowable polysilazane film to a silicon oxide film; and
densifying the silicon oxide film.

11. The method of claim 10, wherein curing comprises exposing the flowable polysilazane film to ultraviolet (UV) light.

12. The method of claim 10, wherein densifying the silicon oxide film comprises treating the silicon oxide film with inductively coupled plasma (ICP) at a temperature less than about 400° C.

13. The method of claim 10, wherein depositing the film comprises exposing the top surface of the film stack to a precursor mixture, the precursor mixture comprising one or more of a silane, trisilylamine (TSA), and a reactant gas.

14. The method of claim 13, wherein the silane comprises one or more of silane, disilane, trisilane, tetrasilane, higher order silanes, and substituted silanes, and wherein the reactant gas comprises one or more of argon (Ar), oxygen (O₂), hydrogen (H₂), nitrogen (N₂), hydrogen/nitrogen (H₂/N₂), and ammonia (NH₃).

15. The method of claim 13, wherein the precursor mixture comprises silane, trisilylamine (TSA) and the reactant gas.

16. The method of claim 13, wherein exposing the film to the remote plasma source (RPS) dissociates the reactant gas and generates a radical that reacts with one or more of the silane and trisilylamine (TSA).

17. A non-transitory computer readable medium including instructions, that, when executed by a controller of a processing chamber, causes the processing chamber to perform operations of:
expose a substrate surface to a precursor mixture to form a film on the substrate surface;
expose the film to a remote plasma source to deposit a flowable polysilazane film;
cure the flowable polysilazane film;
convert the flowable polysilazane film to a silicon oxide film; and
densify the silicon oxide film.

18. The non-transitory computer readable medium of claim 17, wherein curing comprises exposing the flowable polysilazane film to ultraviolet (UV) light, and wherein densifying the silicon oxide film comprises treating the silicon oxide film with inductively coupled plasma (ICP) at a temperature less than about 400° C.

19. The non-transitory computer readable medium of claim 17, wherein the precursor mixture comprises one or more of a silane, trisilylamine (TSA), and a reactant gas, the silane comprising one or more of silane, disilane, trisilane, tetrasilane, higher order silanes, and substituted silanes, and the reactant gas comprising one or more of argon (Ar), oxygen (O₂), hydrogen (H₂), nitrogen (N₂), hydrogen/nitrogen (H₂/N₂), and ammonia (NH₃).

20. The non-transitory computer readable medium of claim 19, wherein exposing the film to the remote plasma source (RPS) dissociates the reactant gas and generates a radical that reacts with one or more of the silane and trisilylamine (TSA).
